(19) United States
(12) Patent Application Publication
(10) Pub. No.: US 2009/0027081 A1
(43) Pub. Date: Jan. 29, 2009

(54) Eight Transistor Tri-State Driver Implementing Cascade Structures To Reduce Peak Current Consumption, Layout Area and Slew Rate

(75) Inventors: Aleksandr Kaplun, Whitsett, NC (US); Zhibin Cheng, Cary, NC (US); James Alan Tuvell, Austin, TX (US); Sam Gat-Shang Chu, Round Rock, TX (US)

Correspondence Address: Robert A. Voigt, Jr.;WINSTEAD SECHREST & MINICK PC, PO BOX 50784, DALLAS, TX, 75201, US

(73) Assignee: International Business Machines Corporation, Armonk, NY (US)

(21) Appl. No.: 11/782,961

(22) Filed: Jul. 25, 2007

(51) Int. Cl. H03K 19/0948

(52) U.S. Cl. 326/58

(57) ABSTRACT

An eight-transistor tri-state driver. The tri-state driver implements multiple cascade structures where each cascade structure may refer to a pair of complementary transistors serially connected. Each cascade structure may include a p-conductivity type transistor serially connected to a n-conductivity type transistor. By implementing cascade structures in a tri-state driver, there is a lower peak current consumption, a reduced slew rate as well as a reduction in the amount of layout area used in comparison to the classic tri-state drivers.

### TECHNICAL FIELD

The present invention relates to the field of tri-state drivers, and more particularly to an eight transistor tri-state driver implementing cascade structures to reduce peak current consumption, layout area and slew rate.

### BACKGROUND INFORMATION

A tri-state driver is a logic circuit having an output terminal which can be driven to any of three states. Current can be supplied into the output terminal in a first state, current can be drawn from the output terminal in a second state, or the output can assume an isolated (floating) condition in a third state. That is, a tri-state driver provides an inactive state (low or zero), an active state (high or one) and an intermediate, high-impedance state (Hi-Z).

Tri-state drivers may be used in various applications, such as avoiding bus contention. Bus contention may refer to the situation when two devices simultaneously drive a bus and the transmitted information becomes garbled and unreliable. Bus contention may be avoided by requiring the tri-state driver to be in an intermediate, high-impedance state at a particular time, such as when a control signal for a processing unit is switched from one logic level to another logic level. Other applications include being used for on-chip interconnects. For example, the tri-state driver may be in a high-impedance state when incoming signals are not changing thereby reducing power consumption.

One approach for obtaining tri-state operation is to drive the output terminal with a pair of complementary output transistors serially connected between a power supply node and ground, and to provide a logic circuit for separately controlling the gates of the complementary transistor pair. In response to one condition of a control signal, the tri-state driver applies the same polarity signals to the control electrodes of the output transistors, clamping the output terminal either to the power supply point or to ground depending upon the sense of the control signal. In response to another condition of the control signal, the tri-state driver supplies suitable complementary signals to the complementary transistors, to bias both of them off concurrently and thereby to isolate the output terminal. This approach offers low impedance symmetrical drive with low shunt capacity to the output and provides high speed operation.

Tri-state drivers may be devised with various designs. Two classic designs for tri-state drivers include the four transistor tri-state driver illustrated in FIG. 1 and the twelve transistor tri-state driver illustrated in FIG. 2. Referring to FIG. 1, tri-state driver 100 includes four transistors (transistors of n-conductivity type are identified by the letter N followed by a reference number; whereas, transistors of p-conductivity type are identified by the letter P followed by a reference number) P1, N1, P2 and N2. The source of transistor P1 is coupled to a positive potential of V_{DD} volts. The source of transistor N1 is coupled to ground. The gates of transistors P1, N1 are coupled to an input data signal. Tri-state driver 100 further includes transistor P2 where the gate of transistor P2 is coupled to an enable signal. The drain of transistor P2 is coupled to the drain of transistor N2 where the gate of transistor N2 is coupled to the inverse of the logic state of the enable signal (designated as a bar above the enable signal in FIG. 1). Further, the drains of transistors P2, N2 are coupled to the output. Further, the source of transistor P2 is coupled to the drains of transistors P1, N1 and the source of transistor N2 is coupled to the drains of transistors N1, P1. Further, the drain of transistor P1 is coupled to the drain of transistor N1. A detail discussion of the operation of tri-state driver 100 will not be described herein for the sake of brevity. The general operation characteristics of tri-state driver 100 will be discussed further below.

Referring to FIG. 2, tri-state driver 200 is a twelve transistor tri-state driver that includes NAND gates 201, 202 coupled to a complementary pair of transistors, P1, N1. The source of transistor P1 is coupled to a positive potential of V_{DD} volts; whereas, the source of transistor N1 is coupled to ground. The drains of transistors P1, N1 are coupled to the output of ti-state driver 200. The two inputs of NAND gate 201 include an input data signal and an enable signal which are coupled to NAND gate 201 via resistors R1, R2, respectively. The two inputs of NAND gate 202 include an input data signal and the inverse of the logic state of the enable signal (designated as a bar above the enable signal in FIG. 2) which are coupled to NAND gate 201 via resistors R3, R4, respectively. The output of NAND gate 201 is coupled to the gate of transistor P1 via resistor R5. The output of NAND gate 202 is coupled to the gate of transistor N1 via resistor R6. A detail discussion of the operation of tri-state driver 200 will not be described herein for the sake of brevity. The general operation characteristics of tri-state driver 200 will be discussed further below.

Tri-state drivers 100, 200 have relatively high peak current consumption, use a relatively large layout area and have a relatively high slew rate (referring to the maximum rate of change of a signal). If a tri-state driver could be designed with a lower peak current consumption, a reduced slew rate, as well as a reduction in the amount of layout area used, then a more optimized tri-state driver could be used, such as for on-chip interconnects.

Therefore, there is a need in the art for an improved tri-state driver with a lower peak current consumption, a reduced slew rate, as well as a reduction in the amount of layout area.

### SUMMARY

The problems outlined above may at least in part be solved in some embodiments by having a tri-state driver implement multiple cascade structures where each cascade structure may refer to a pair of complementary transistors serially connected. Each cascade structure may include a p-conductivity type transistor serially connected to a n-conductivity type transistor. By implementing cascade structures in a tri-state driver, there is a lower peak current consumption, a reduced slew rate as well as a reduction in the amount of layout area used in comparison to the classic tri-state drivers. The peak current consumption and the slew rate are reduced at least in part due to the complementary structure of these cascade structures, which prevent charge sharing effects. Charge sharing may refer to having the charge at a node shared among multiple connected structures. Further, the layout area may be reduced by using a smaller number of transistors as well as by being able to use smaller sized transistors than the classic tri-state drivers.

In one embodiment of the present invention, a tri-state driver comprises a first cascade structure coupled to a data input signal. The tri-state driver further comprises a second cascade structure coupled to an enable signal. The tri-state drive additionally comprises a third cascade structure coupled to an inverse of a logic state of the enable signal, where the second and third cascade structures are coupled to the first cascade structure. The tri-state driver further comprises a fourth cascade structure coupled to the second and third cascade structures, where the fourth cascade structure is coupled to an output of the tri-state driver.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE DRAWINGS

A better understanding of the present invention can be obtained when the following detailed description is considered in conjunction with the following drawings, in which:

FIG. 1 illustrates a classic four transistor tri-state driver;

FIG. 2 illustrates a classic twelve transistor tri-state driver;

FIG. 3 illustrates an eight transistor tri-state driver configured in accordance with an embodiment of the present invention;

FIG. 4 is a truth table of the logical states of a “hi” node in the tri-state driver of FIG. 3 which are based on the logical states of the input data signal and the logical states of the enable signal in accordance with an embodiment of the present invention;

FIG. 5 is a truth table of the logical states of a “lo” node in the tri-state driver of FIG. 3 which are based on the logical states of the input data signal and the logical states of the enable signal in accordance with an embodiment of the present invention; and

FIG. 6 is a truth table of the logical states of the output of the tri-state driver of FIG. 3 which are based on the logical states of the “hi” and “lo” nodes in accordance with an embodiment of the present invention.

### DETAILED DESCRIPTION

The present invention comprises an eight transistor tri-state driver. In one embodiment of the present invention, the tri-state driver implements multiple cascade structures where each cascade structure may refer to a pair of complementary transistors serially connected. Each cascade structure may include a p-conductivity type transistor serially connected to a n-conductivity type transistor. By implementing cascade structures in a tri-state driver, there is a lower peak current consumption, a reduced slew rate as well as a reduction in the amount of layout area used in comparison to the classic tri-state drivers. The peak current consumption and the slew rate are reduced at least in part due to the complementary structure of these cascade structures, which prevent charge sharing effects. Charge sharing may refer to having the charge at a node shared among multiple connected structures. Further, the layout area may be reduced by using a smaller number of transistors as well as by being able to use smaller sized transistors than the classic tri-state drivers.

In the following description, numerous specific details are set forth to provide a thorough understanding of the present invention. However, it will be apparent to those skilled in the art that the present invention may be practiced without such specific details. In other instances, well-known circuits have been shown in block diagram form in order not to obscure the present invention in unnecessary detail. For the most part, details considering timing considerations and the like have been omitted inasmuch as such details are not necessary to obtain a complete understanding of the present invention and are within the skills of persons of ordinary skill in the relevant art.

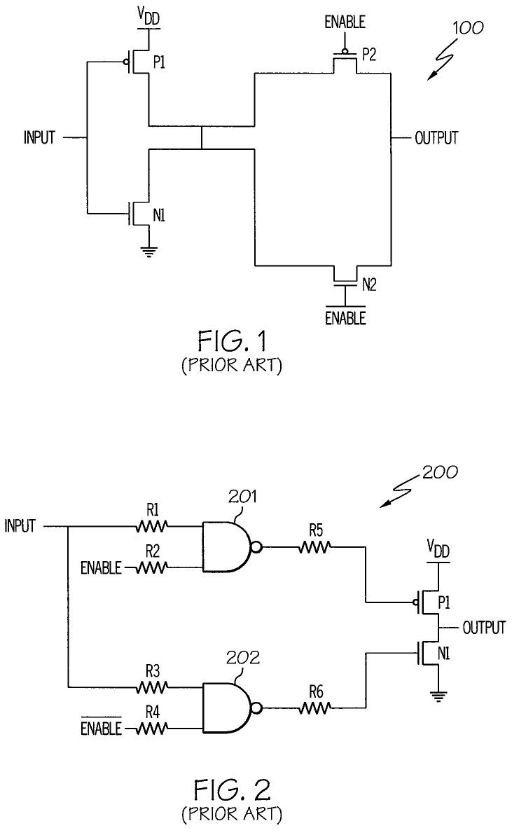

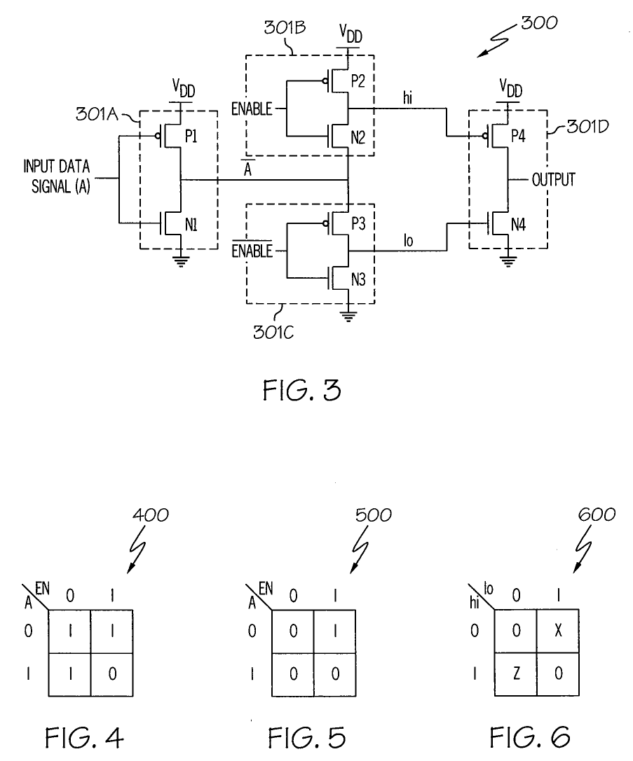

As stated in the Background Information section, classic tri-state drivers, such as tri-state drivers 100, 200 (FIGS. 1-2), have relatively high peak current consumption, use a relatively large layout area and have a relatively high slew rate (referring to the maximum rate of change of a signal). If a tri-state driver could be designed with a lower peak current consumption, a reduced slew rate, as well as a reduction in the amount of layout area used, then a more optimized tri-state driver could be used, such as for on-chip interconnects. Therefore, there is a need in the art for an improved tri-state driver with a lower peak current consumption, a reduced slew rate, as well as a reduction in the amount of layout area. The tri-state driver of FIG. 3 is an improved tri-state driver with a lower peak current consumption, a reduced slew rate, as well as a reduction in the amount of layout area. A detail discussion of the operation of such a tri-state driver is provided below.

### FIG. 3—Tri-State Driver

FIG. 3 illustrates an eight transistor tri-state driver 300 configured in accordance with an embodiment of the present invention. Tri-state driver 300 may be implemented in any low power and high performance circuit, especially for on-chip interconnects.

Referring to FIG. 3, tri-state driver 300 includes multiple cascade structures 301A-D. Cascade structures may collectively or individually be referred to as cascade structures 301 or cascade structure 301, respectively. Cascade structure 301, as used herein, may refer to a pair of complementary transistors serially connected. For example, cascade structure 301A includes a pair of complementary transistors serially connected (transistors of n-conductivity type are identified by the letter N followed by a reference number; whereas, transistors of p-conductivity type are identified by the letter P followed by a reference number), namely transistor P1 serially connected to transistor N1. Similarly, cascade structure 301B includes transistor P2 serially connected to transistor N2. Cascade structure 301C includes transistor P3 serially connected to transistor N3 and cascade structure 301D includes transistor P4 serially connected to N4.

Referring to cascade structure 301 of FIG. 3, the source of transistor P1 is coupled to a positive potential of V_{DD} volts. The drain of transistor P1 is coupled to the drain of transistor N1. The source of transistor N1 is coupled to ground. Further, the gates of transistors P1 and N1 are coupled to an input data signal (designated as “A” in FIG. 3).

Referring to cascade structure 302 of FIG. 3, the source of transistor P2 is coupled to a positive potential of V_{DD} volts. The drain of transistor P2 is coupled to the drain of transistor N2. The source of transistor N2 is coupled to a node at a logical state of the inverse of the data input signal (designated as a bar above the input data signal in FIG. 3). Further, the gates of transistors P2 and N2 are coupled to an enable signal. Additionally, the drains of transistors P2 and N2 are connected to a node designated as the “hi” node which will be discussed in more detail further below.

Referring to cascade structure 303 of FIG. 3, the source of transistor P3 is coupled to the node at the logical state of the inverse of the data input signal (designated as a bar above the input data signal in FIG. 3). The drain of transistor P3 is coupled to the drain of transistor N3. The source of transistor N3 is coupled to ground. Further, the gates of transistors P3 and N3 are coupled to the inverse of the enable signal (designated as a bar above the enable signal in FIG. 3). Additionally, the drains of transistors P3 and N3 are connected to a node designated as the “lo” node which will be discussed in more detail further below.

Referring to cascade structure 304 of FIG. 3, the source of transistor P4 is coupled to a positive potential of V_{DD} volts. The drain of transistor P4 is coupled to the drain of transistor N4. The source of transistor N4 is coupled to ground. Further, the gates of transistors P4 and N4 are coupled to the nodes designated as “hi” and “lo,” respectively. Additionally, the drains of transistors P4 and N4 are connected to the output of tri-state driver 300.

The operation of tri-state driver 300 will now be discussed in connection with FIGS. 4-6. FIG. 4 is a truth table 400 of the logical states of the “hi” node based on the logical states of the input data signal and the enable signal in accordance with an embodiment of the present invention. FIG. 5 is a truth table 500 of the logical states of the “lo” node based on the logical states of the input data signal and the enable signal in accordance with an embodiment of the present invention. FIG. 6 is a truth table 600 of the logical states of the output of tri-state driver 300 based on the logical states of the “hi” and “lo” nodes in accordance with an embodiment of the present invention.

A brief description of the operation of cascade structure 301B, including the various logical states of the “hi” node, will now be discussed. Referring to FIG. 3, in conjunction with FIG. 4, when the input data signal (designated as “A”) is at a low logical state, then transistor P1 is activated (i.e., turned on) and transistor N1 is deactivated (i.e., turned off). Further, when the input data signal is at a low logical state, the inverse of the input data signal (designated as a bar above “A”) is at a high logical state.

When the enable signal (designated as either “enable” or “EN”) is at a low logical state, transistor P2 is activated and transistor N2 is deactivated. When both the input data signal is at a low logical state (hence the inverse of the input data signal is at a high logical state) and the enable signal is at a low logical state, the logical state at the “hi” node is at the high logical state (designated as “1” in truth table 400). The logical state at the “hi” node is high since P2 is activated and N2 is deactivated thereby causing the “hi” node to pull up to the positive potential of V_{DD} volts.

When the enable signal (designated as either “enable” or “EN”) is at a high logical state, transistor P2 is deactivated and transistor N2 is activated. When both the input data signal is at a low logical state (hence the inverse of the input data signal is at a high logical state) and the enable signal is at a high logical state, the logical state at the “hi” node is at the high logical state (designated as “1” in truth table 400). The logical state at the “hi” node is high since the logical state at the node connected to the source of transistor N2 is high (inverse of the input data signal is at a high logical state) thereby causing the signal from that node to flow through transistor N2 to the “hi” node. This is possible since transistor N2 is bidirectional.

When the input data signal (designated as “A”) is at a high logical state, then transistor P1 is deactivated and transistor N1 is activated. Further, when the input data signal is at a high logical state, the inverse of the input data signal (designated as a bar above “A”) is at a low logical state.

As discussed above, when the enable signal (designated as either “enable” or “EN”) is at a low logical state, transistor P2 is activated and transistor N2 is deactivated. When both the input data signal is at a high logical state (hence the inverse of the input data signal is at a low logical state) and the enable signal is at a low logical state, then the logical state at the “hi” node is at the high logical state (designated as “1” in truth table 400). The logical state at the “hi” node is high since P2 is activated and N2 is deactivated thereby causing the “hi” node to pull up to the positive potential of V_{DD} volts.

As discussed above, when the enable signal (designated as either “enable” or “EN”) is at a high logical state, transistor P2 is deactivated and transistor N2 is activated. When both the input data signal is at a high logical state (hence the inverse of the input data signal is at a low logical state) and the enable signal is at a high logical state, then the logical state at the “hi” node is at the low logical state (designated as “0” in truth table 400). The logical state at the “hi” node is low since transistor N2 is activated and the node connected to the source of transistor N2 is low (the inverse of the input data signal is at a low logical state) which causes the current to flow down through transistor N2 towards cascade structure 301C.

A brief description of the operation of cascade structure 301C, including the various logical states of the “lo” node, will now be discussed. When the enable signal is at a low logical state, then the inverse of the enable signal (designated as a bar above the enable signal) is at a high logical state. When the inverse of the enable signal is at a high logical state, then transistor P3 is deactivated and transistor N3 is activated.

When both the input data signal is at a low logical state (hence the inverse of the input data signal is at a high logical state) and the enable signal is at a low logical state (hence the inverse of the enable signal is at a high logical state), then the logical state at the “lo” node is at the low logical state (designated as “0” in truth table 500). The logical state at the “lo” node is low since transistor P3 is deactivated and transistor N3 is activated thereby causing the “lo” node to pull down to ground.

Further, when both the input data signal is at a high logical state (hence the inverse of the input data signal is at a low logical state) and the enable signal is at a low logical state (hence the inverse of the enable signal is at a high logical state), then the logical state at the “lo” node is at the low logical state (designated as “0” in truth table 500). The logical state at the “lo” node is low since transistor P3 is deactivated and transistor N3 is activated thereby causing the “lo” node to pull down to ground.

When the enable signal is at a high logical state (hence the inverse of the enable signal is at a low logical state), then transistor P3 is activated and transistor N3 is deactivated.

When both the input data signal is at a low logical state (hence the inverse of the input data signal is at a high logical state) and the enable signal is at a high logical state (hence the inverse of the enable signal is at a low logical state), then the logical state at the “lo” node is at the high logical state (designated as “1” in truth table 500). The logical state at the “lo” node is high since transistor P3 is activated, the node connected to the source of transistor P3 is high (the inverse of the input data signal is at a high logical state), and transistor N3 is deactivated thereby causing the “lo” node to pull to a high logical state.

However, if both the input data signal is at a high logical state (hence the inverse of the input data signal is at a low logical state) and the enable signal is at a high logical state (hence the inverse of the enable signal is at a low logical state), then the logical state at the “lo” node is at the low logical state (designated as “0” in truth table 500). The logical state at the “lo” node is low since the node connected to the source of transistor P3 (which is activated) is low which causes the current to flow up through transistor P3 towards cascade structure 301B thereby pulling the “lo” node down towards ground.

Based on the logical states of the “hi” and “lo” nodes, the output of tri-state inverter 300 may be in one of three states: inactive state (low or zero), an active state (high or one) and an intermediate, high-impedance state (Hi-Z) as discussed below in connection with FIG. 6.

Referring to FIG. 3, in conjunction with FIG. 6, when the “hi” node is at a low logical state, then transistor P4 is activated. Further, when the “lo” node is at a low logical state, then transistor N4 is deactivated. When transistor P4 is activated and transistor N4 is deactivated, then the output is pulled up to the positive potential of V_{DD} volts (designated as “1” in truth table 600). When this occurs, tri-state driver 300 is said to be in the active state.

When the “hi” node is at a high logical state, then transistor P4 is deactivated. When the “hi” node is at a high logical state and the “lo” node is at a low logical state, then the output is at the high-impedance state (designated as “Z” in truth table 600). Tri-state driver 300 enters the high-impedance state when both transistors P4 and N4 are deactivated.

When the “lo” node is at a high logical state, transistor N4 is activated. When both the “hi” and “lo” nodes are at a high logical state, the output of tri-state driver is at a low logical state (designated as “0” in truth table 600). Since transistor P4 is deactivated and transistor N4 is activated, the output is pulled down to ground.

Referring to FIGS. 4 and 5, it is illustrated that there is not a case of the “lo” node being at a high logical state when the “hi” node is at a low logical state. Hence, referring to FIG. 6, there is an indication in truth table 600 (designated as an “X”) that the case of the “lo” node being at a high logical state when the “hi” node is at a low logical state does not occur.

Referring to FIG. 3, by implementing cascade structures 301 in tri-state driver 300, there is a lower peak current consumption, a reduced slew rate as well as a reduction in the amount of layout area used in comparison to the classic tri-state drivers. The peak current consumption and the slew rate are reduced at least in part due to the complementary structure of these cascade structures 301, which prevent charge sharing effects. Charge sharing may refer to having the charge at a node (e.g., node at the inverse logic level of the input data signal) shared among multiple cascade structures 301 (e.g., cascade structures 301B, 301C). The layout area may be reduced by using a smaller number of transistors (eight transistors in comparison to the classic twelve transistor tri-state driver as illustrated in FIG. 2) and being able to use smaller sized transistors (tri-state driver 300 is able to use smaller sized transistors than the classic four transistor tri-state driver as illustrated in FIG. 1. A smaller number of transistors and smaller sized transistors may be used in tri-state driver 300 in comparison to the classic tri-state drivers because tri-state driver 300 has a complementary structure in its pre-driving and driving stages which have a stronger driving strength compared to a same sized, single pass-gate driver, as illustrated in FIG. 1. Therefore, for a given load, a smaller number and smaller sized transistors can be utilized in tri-state driver 300.

Although the tri-state driver is described in connection with several embodiments, it is not intended to be limited to the specific forms set forth herein, but on the contrary, it is intended to cover such alternatives, modifications and equivalents, as can be reasonably included within the spirit and scope of the invention as defined by the appended claims. It is noted that the headings are used only for organizational purposes and not meant to limit the scope of the description or claims.

1. A tri-state driver comprising:
a first cascade structure coupled to a data input signal;
a second cascade structure coupled to an enable signal;
a third cascade structure coupled to an inverse of a logic state of said enable signal, wherein said second and third cascade structures are coupled to said first cascade structure; and
a fourth cascade structure coupled to said second and third cascade structures, wherein said fourth cascade structure is coupled to an output of said ti-state driver.

2. The tri-state driver as recited in claim 1, wherein each of said first, second, third and fourth cascade structures comprise a transistor of p-conductivity type coupled serially to a transistor of n-conductivity type.

3. The tri-state driver as recited in claim 2, wherein a source of a first n-conductivity type transistor of said second cascade structure is coupled to a drain of a first p-conductivity type transistor and a drain of a second n-conductivity type transistor of said first cascade structure.

4. The tri-state driver as recited in claim 3, wherein a source of a second p-conductivity type transistor of said third cascade structure is coupled to said drain of said first p-conductivity type transistor and said drain of said second n-conductivity type transistor of said first cascade structure.

5. The tri-state driver as recited in claim 4, wherein said source of said first n-conductivity type transistor of said second cascade and said source of said second p-conductivity type transistor of said third cascade is coupled to a first node at an inverse of a logic state of said data input signal.

6. The tri-state driver as recited in claim 5, wherein a drain of a third p-conductivity type transistor of said second cascade structure and a drain of said first n-conductivity type transistor of said second cascade structure is coupled to a second node.

7. The tri-state driver as recited in claim 6, wherein a drain of said second p-conductivity type transistor and a drain of a third n-conductivity type transistor of said third cascade structure is coupled to a third node.

8. The tri-state driver as recited in claim 7, wherein said second node has a high logical state when said data input signal is at a low logical state, wherein said second node has said high logical state when said data input signal is at a high logical state and when said enable signal is at a low logical state, wherein said second node has a low logical state when said data input signal is at said high logical state and when said enable signal is at a high logical state.

9. The tri-state driver as recited in claim 8, wherein said third node has a low logical state when said data input signal is at said high logical state, wherein said third node has said low logical state when said data input signal is at said low logical state and when said enable signal is at said low logical state, wherein said third node has a high logical state when said data input signal is at said low logical state and when said enable signal is at said high logical state.

10. The tri-state driver as recited in claim 9, wherein a gate of a fourth p-conductivity type transistor of said fourth cascade structure is coupled to said second node, wherein a gate of a fourth n-conductivity type transistor of said fourth cascade structure is coupled to said third node.

11. The tri-state driver as recited in claim 10, wherein a drain of said fourth p-conductivity type transistor of said fourth cascade structure and a drain of said fourth n-conductivity type transistor of said fourth cascade structure is coupled to an output of said tri-state driver.

12. The tri-state driver as recited in claim 11, wherein said output of said tri-state driver is at a high logical state when said second node is at a low logical state and when said third node is at a low logical state, wherein said output of said tri-state driver is at a low logical state when said second node is at a high logical state and when said third node is at a high logical state, wherein said output of said tri-state driver is at a high-impedance state when said second node is at said high logical state and when said third node is at said low logical state.

13. The tri-state driver as recited in claim 2, wherein a gate of a first p-conductivity type transistor of said second cascade structure is coupled to said enable signal, wherein a gate of a first n-conductivity type transistor of said second cascade structure is coupled to said enable signal.

14. The tri-state driver as recited in claim 2, wherein a gate of a first p-conductivity type transistor of said third cascade structure is coupled to said inverse of said logic state of said enable signal, wherein a gate of a first n-conductivity type transistor of said third cascade structure is coupled to said inverse of said logic state of said enable signal.

15. The tri-state driver as recited in claim 2, wherein a gate of a first p-conductivity type transistor of said fourth cascade structure is coupled to a drain of a second p-conductivity type transistor and a drain of a first n-conductivity type transistor of said second cascade structure.

16. The tri-state driver as recited in claim 15, wherein a gate of a second n-conductivity type transistor of said fourth cascade structure is coupled to a drain of a third p-conductivity type transistor and a drain of a third n-conductivity type transistor of said third cascade structure.

17. The tri-state driver as recited in claim 16, wherein a drain of said first p-conductivity type transistor of said fourth cascade structure and a drain of said second n-conductivity type transistor of said fourth cascade structure is coupled to an output of said tri-state driver.

18. The ti-state driver as recited in claim 1, wherein said tri-state driver is used for on-chip interconnects.
